(19) United States
(12) Patent Application Publication
(10) Pub. No.: US 2010/0213987 A1
(43) Pub. Date: Aug. 26, 2010

(54) SEMICONDUCTOR MEMORY DEVICE AND DRIVING METHOD FOR THE SAME

(76) Inventors: Keita TAKAHASHI, Nara (JP); Nobuyoshi Takahashi, Niigata (JP)

Correspondence Address: MCDERMOTT WILL & EMERY LLP, 600 13TH STREET, NW, WASHINGTON, DC, 20005-3096, US

(21) Appl. No.: 12/632,335

(22) Filed: Dec. 7, 2009

(30) Foreign Application Priority Data
Feb. 20, 2009 (JP) 2009-038102

(51) Int. Cl. H03K 17/687; H01L 29/78

(52) U.S. Cl. 327/109; 257/328; 257/E29.256

(57) ABSTRACT

A semiconductor device includes an element to be protected formed on a semiconductor substrate, a first protection transistor, and a second protection transistor. The first protection transistor is formed on a first well of a first conductivity type formed in an upper portion of a deep well of a second conductivity type. The second protection transistor is formed on a second well of the second conductivity type. A second source/drain diffusion layer is electrically connected with a third source/drain diffusion layer and at the same potential as the first well. A fourth source/drain diffusion layer is electrically connected with a second diffusion layer and at the same potential as the second well and the second diffusion layer.

### CROSS-REFERENCE TO RELATED APPLICATION

This application claims priority to Japanese Patent Application No. 2009-038102 filed on Feb. 20, 2009, the disclosure of which including the specification, the drawings, and the claims is hereby incorporated by reference in its entirety.

### BACKGROUND

The present disclosure relates to a semiconductor memory device and a driving method for the same, and more particularly to a semiconductor memory device including a local charge storage nonvolatile memory and the like and a driving method for such a semiconductor memory device.

In a local charge storage nonvolatile memory that includes an ONO film as a charge storage film and uses channel hot electrons for write and hot holes generated by interband tunneling for erase, once the memory is subjected to charge injection due to charge-up during a diffusion process, it is often difficult to remove the charge after completion of the fabrication process. Hence, techniques for suppressing charge-up damage on memory elements during diffusion process are important. In relation to this, a technique in which a protection element is connected to the gate electrode of a memory element during diffusion process for suppressing charge-up damage has been examined (see U.S. Pat. No. 6,337,502, for example).

FIG. 10 depicts a conventional method for suppressing charge-up damage. As shown in FIG. 10, a charge-up protection transistor 152 is connected to the gate electrode of an element 150 to be protected as a memory element via an interconnect 140. When positive charge is applied to the gate electrode of the element 150 during wiring process, the positive charge is also applied to the gate electrode of the protection transistor 152 simultaneously. This turns ON the protection transistor 152, allowing source-drain conduction. Hence, the charge escapes to a substrate 141 without being stored in the gate electrode of the element 150 to be protected. When negative charge is applied to the gate electrode of the element 150 to be protected, a source/drain diffusion layer and a well diffusion layer are forward-biased. Hence, the charge escapes to the substrate 141 without being stored in the gate electrode of the element 150 to be protected.

With the above operation, charge-up occurring in and after the first-layer wiring process can be suppressed to about ±1 V.

Note that the term “source/drain diffusion layer” is defined as indicating either one of the source diffusion layer and the drain diffusion layer belonging to one transistor. When one of the two source/drain diffusion layers belonging to one transistor functions as the source diffusion layer, the other should function as the drain diffusion layer.

### SUMMARY

However, the above conventional technique has the following problem. When a negative voltage is applied to the memory element after completion of the fabrication process, conduction occurs from the drain of the transistor as the protection element to the substrate. Therefore, a negative bias cannot be applied to the completed memory element. Another problem is that since the element to be protected and the charge-up protection transistor are connected to each other via an interconnect, the protection effect works only in and after the wiring process. Hence, the memory element cannot be protected from charging during diffusion process in the front end of line (FEOL) process that is a fabrication process before the wiring (back end of line: BEOL) process.

As memory elements have become finer, the influence of the charge-up during diffusion process in the FEOL process on variations in the initial threshold voltage (Vt) of memory cells has become too great to neglect, and this has caused a major problem. This is because of due to the following circumstances, among others: low-temperature processes are necessary for fabrication of finer memory elements; and a fabricating machine causing large charge-up, such as one for high-density plasma etching, must be used for microfabrication. For example, when cobalt silicide is used in a middle end of line (MEOL) process, a low-temperature process at about 650° C. or less is necessary at and after formation of the cobalt silicide. When nickel silicide is used, a low-temperature process at about 450° C. or less is necessary at and after formation of the nickel silicide.

With the reduction in the process temperature, it is difficult to insert a heat treatment process of extracting charge stored in the FEOL process (preferably at 700° C. or more) in and after the MEOL process. For this reason, it is insufficient to protect memory elements only in and after the wiring process. Also, measures against charge-up during diffusion process are also important since the oxide-nitride-oxide (ONO) film that is to be the gate insulating film of memory elements is thinned. For example, when the thickness of the ONO film decreases from 30 nm to 15 nm, the electric field applied to the ONO film will be doubled if a high voltage is applied due to charging during diffusion process in the FEOL level. Hence, thinning of the ONO film increases the possibility of causing charge injection that may vary the initial Vt. Due to the circumstances described above, the influence of charge-up during diffusion process becomes eminent as memory elements become finer.

To solve the above problems, an object of the present disclosure is providing a semiconductor device in which high voltages of both positive and negative polarities required for driving a memory element can be applied to the memory element after completion of the fabrication process, and permitting protection of a memory element from charge-up during diffusion process in the FEOL process within a voltage range including a low voltage, positive or negative, as required.

To attain the above object, a semiconductor device according to the present disclosure includes a series structure of a protection transistor formed on a first well of a first conductivity type and a protection transistor formed on a second well of a second conductivity type.

Specifically, the illustrative semiconductor device includes: a deep well of a second conductivity type formed in a semiconductor substrate of a first conductivity type; a first well of the first conductivity type formed in an upper portion of the deep well; a second well of the second conductivity type formed in the semiconductor substrate; an element to be protected formed on the semiconductor substrate, the element having a protected element electrode; a first protection transistor formed on the first well; a second protection transistor formed on the second well; a first diffusion layer of the second conductivity type formed in the first well to be electrically connected with the protected element electrode; and a second diffusion layer of the first conductivity type formed in an upper portion of the semiconductor substrate. The first protection transistor includes a first gate electrode formed on the first well and first and second source/drain diffusion layers of the second conductivity type formed in the semiconductor substrate adjacent to the gate electrode. The second protection transistor includes a second gate electrode formed on the second well and third and fourth source/drain diffusion layers of the first conductivity type formed in the semiconductor substrate adjacent to the gate electrode. The first source/drain diffusion layer is in contact with the first diffusion layer. The second source/drain diffusion layer is electrically connected with the third source/drain diffusion layer and at the same potential as the first well. The fourth source/drain diffusion layer is electrically connected with the second diffusion layer and at the same potential as the second well and the second diffusion layer.

The illustrative semiconductor device includes the first protection transistor formed on the first well of the first conductivity type and the second protection transistor formed on the second well of the second conductivity type. Hence, the element to be protected can be protected from charge-up of both positive and negative polarities during diffusion process at a low voltage of about ±1 V. Also, after completion of the fabrication process, high voltages of both positive and negative polarities of about ±10 V can be applied to the element to be protected. Moreover, the source/drain diffusion layer of the first protection transistor and the gate electrode of the element to be protected are connected to each other via the first diffusion layer, and all of the other components can also be electrically connected to one another via diffusion layers. Hence, the element to be protected can be protected in and after the FEOL process before the wiring process.

### BRIEF DESCRIPTION OF THE DRAWINGS

FIGS. 1A and 1B show an illustrative semiconductor device, wherein FIG. 1A is a plan view and FIG. 1B is a cross-sectional view taken along line Ib-Ib in FIG. 1A.

FIG. 2 is a cross-sectional view showing an alteration of the illustrative semiconductor device.

FIG. 3 is a plan view showing another alteration of the illustrative semiconductor device.

FIG. 4 is a circuit diagram of the illustrative semiconductor device.

FIG. 5 is a cross-sectional view showing a step of a method for fabricating the illustrative semiconductor device.

FIG. 6 is a cross-sectional view showing another step of the method for fabricating the illustrative semiconductor device.

FIG. 7 is a cross-sectional view showing yet another step of the method for fabricating the illustrative semiconductor device.

FIG. 8 is a cross-sectional view showing yet another step of the method for fabricating the illustrative semiconductor device.

FIG. 9 is a cross-sectional view showing yet another step of the method for fabricating the illustrative semiconductor device.

FIG. 10 is a circuit diagram of a conventional semiconductor device.

### DETAILED DESCRIPTION

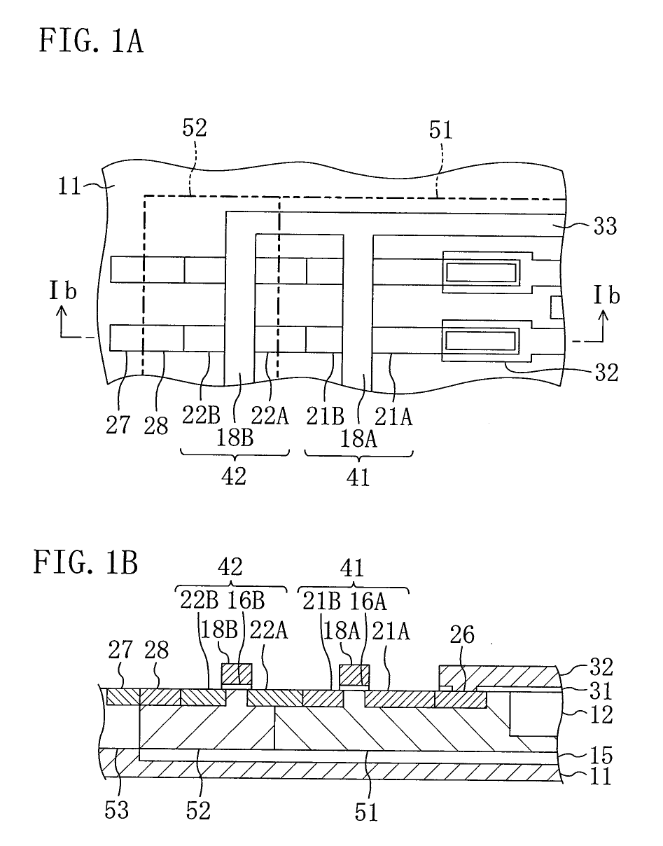

FIGS. 1A and 1B show an illustrative semiconductor device, wherein FIG. 1A is a plan view and FIG. 1B is a cross-sectional view taken along line Ib-Ib in FIG. 1A.

The illustrative semiconductor device includes a memory element as an element to be protected, a first protection transistor 41, and a second protection transistor 42. As shown in FIGS. 1A and 1B, a deep well 15 of a second conductivity type is formed in a region of a semiconductor substrate 11 of a first conductivity type defined by an isolation insulating film 12. A first well 51 of the first conductivity type and a second well 52 of the second conductivity type are formed in an upper portion of the deep well 15. A third well 53 of the first conductivity type is formed in the region other than the deep well 15. The deep well refers to a well having a depth of about 2.5 μm that is formed to include a general well having a depth of about 1.5 μm.

The first protection transistor 41 is formed on the first well 51. The first protection transistor 41 has a first gate electrode 18A formed on the first well 51 with a first gate insulating film 16A interposed therebetween. First and second source/drain diffusion layers 21A and 21B of the second conductivity type are formed in portions of the first well 51 on both sides of the first gate electrode 18A.

The first source/drain diffusion layer 21A is in contact with a first diffusion layer 26 of the second conductivity type formed in the first well 51. A protected element electrode 32 as the gate electrode of the element to be protected is formed on the first diffusion layer 26 with an insulating film 31 having an opening interposed therebetween. The protected element electrode 32 is in contact with the first diffusion layer 26 at the opening.

The second protection transistor 42 is formed on the second well 52. The second protection transistor 42 has a second gate electrode 18B formed on the second well 52 with a second gate insulating film 16B interposed therebetween. Third and fourth source/drain diffusion layers 22A and 22B of the first conductivity type are formed in portions of the second well 52 on both sides of the second gate electrode 18B.

A second diffusion layer 27 of the first conductivity type is formed in the third well 53, and is in contact with a third diffusion layer 28 of the second conductivity type formed in the second well 52. The third diffusion layer 28 is in contact with the fourth source/drain diffusion layer 22B.

The third source/drain diffusion layer 22A extends beyond the boundary between the second well 52 and the first well 51 into the first well 51, to be in contact with the second source/drain diffusion layer 21B.

The element to be protected may be a general memory element. Specifically, it may be a metal/oxide/nitride/oxide/silicon (MONOS) memory having an oxide/nitride/oxide (ONO) insulating film as the gate insulating film, an FG memory having a floating gate (FG) electrode, or a volatile memory such as a static RAM (SRAM) and a dynamic RAM (DRAM). In general, the gate electrode of a memory element is very long and narrow and has a nature susceptible to in-process charge-up damage. Therefore, by adopting this configuration for the semiconductor device, improvement in reliability and yield can be expected. The present disclosure can also be used for protection of any semiconductor element, other than the memory elements, having a nature susceptible to in-process charge-up damage.

In the example shown in FIGS. 1A and 1B, the first gate electrode 18A and the second gate electrode 18B are connected to each other forming a common electrode. However, the first gate electrode 18A and the second gate electrode 18B may be independent electrodes. The antenna ratio improves when the first and second gate electrodes 18A and 18B serve as a common electrode, compared with when they serve as independent electrodes. Therefore, in prevention of charging during the fabrication process, a voltage of the same polarity as the voltage applied to the protected element electrode 32 can be easily applied to the first gate electrode 18A and the second gate electrode 18B, and hence the protection effect can be obtained more stably. Moreover, in the example shown in FIGS. 1A and 1B, the first gate electrode 18A and the second gate electrode 18B are integral with a dummy electrode 33 extending in parallel with the protected element electrode 32. By integrating the first and second gate electrodes 18A and 18B with the dummy electrode 33, the antenna ratio can be further improved.

In the example shown in FIGS. 1A and 1B, the third diffusion layer 28 is formed between the second diffusion layer 27 and the fourth source/drain diffusion layer 22B. However, since it is only required for the fourth source/drain diffusion layer 22B to be at the same potential as the second well 52 and the second diffusion layer 27, the second diffusion layer 27 and the fourth source/drain diffusion layer 22B may be configured to be in direct contact with each other.

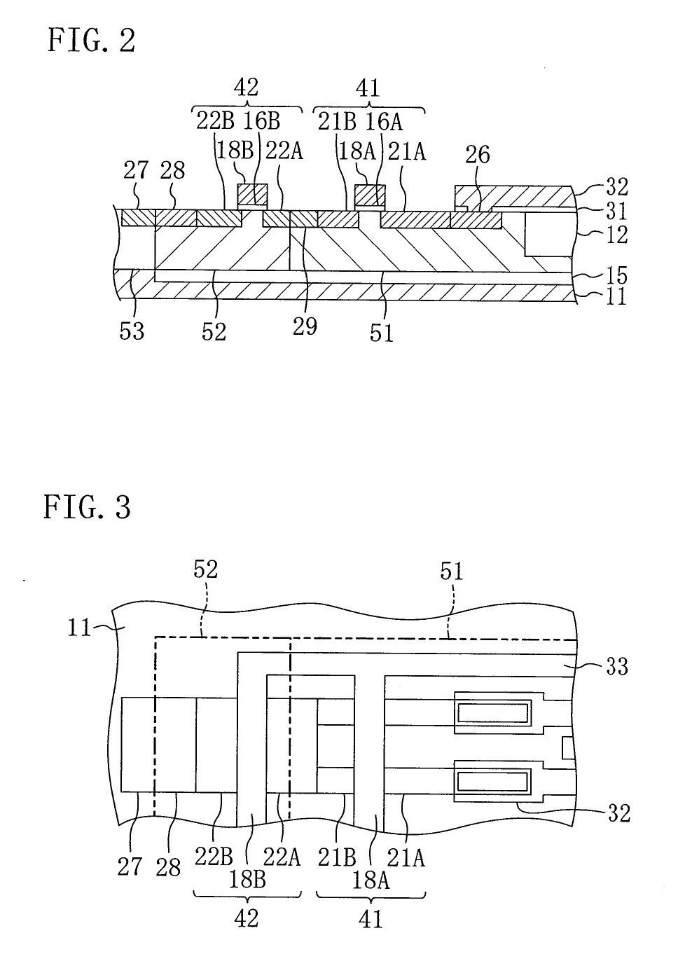

In the illustrated example, the third source/drain diffusion layer 22A extends beyond the boundary between the second well 52 and the first well 51 to be in contact with the second source/drain diffusion layer 21B. However, it is only required for the second source/drain diffusion layer 22B, the third source/drain diffusion layer 22A, and the first well 51 to be at the same potential. Hence, as shown in FIG. 2, the third source/drain diffusion layer 22A and the second source/drain diffusion layer 21B may be connected with each other via a fourth diffusion layer 29 of the first conductivity type formed in the first well 51. The third source/drain diffusion layer 22A and the fourth diffusion layer 29 may not have to be in contact with each other. Instead, the second source/drain diffusion layer 21B and the third source/drain diffusion layer 22A may be in contact with each other at the boundary between the first well 51 and the second well 52, and the second source/drain diffusion layer 21B may be in contact with the fourth diffusion layer formed in the first well 51.

In the structure where the third source/drain diffusion layer 22A extends beyond the boundary between the second well 52 and the first well 51, a portion of the second well 52 inevitably overlaps the deep well 15. However, the second well 52 is not necessarily formed in an upper portion of the deep well 15, or the second well 52 does not have to be at the same potential as the deep well 15.

In FIGS. 1A and 1B, the first source/drain diffusion layer 21A is depicted as clearly distinguished from the first diffusion layer 26. However, it is unnecessary to form the first source/drain diffusion layer 21A and the first diffusion layer 26 clearly separately in the fabrication process. For example, the first source/drain diffusion layer 21A and the first diffusion layer 26 may be formed integrally, and the protected element electrode 32 as the gate electrode of the element to be protected may be connected to such an integrated diffusion layer.

In the example shown in FIG. 1A, the first protection transistor 41 and the second protection transistor 42 are formed for each protected element electrode 32. However, as shown in FIG. 3, while the first protection transistor 41 is formed for each protected element electrode 32, the second protection transistor 42 may be shared between plural protected element electrodes 32. Although the second protection transistor 42 is shared between two protected element electrodes 32 in FIG. 3, it may be shared between three or more protected element electrodes 32.

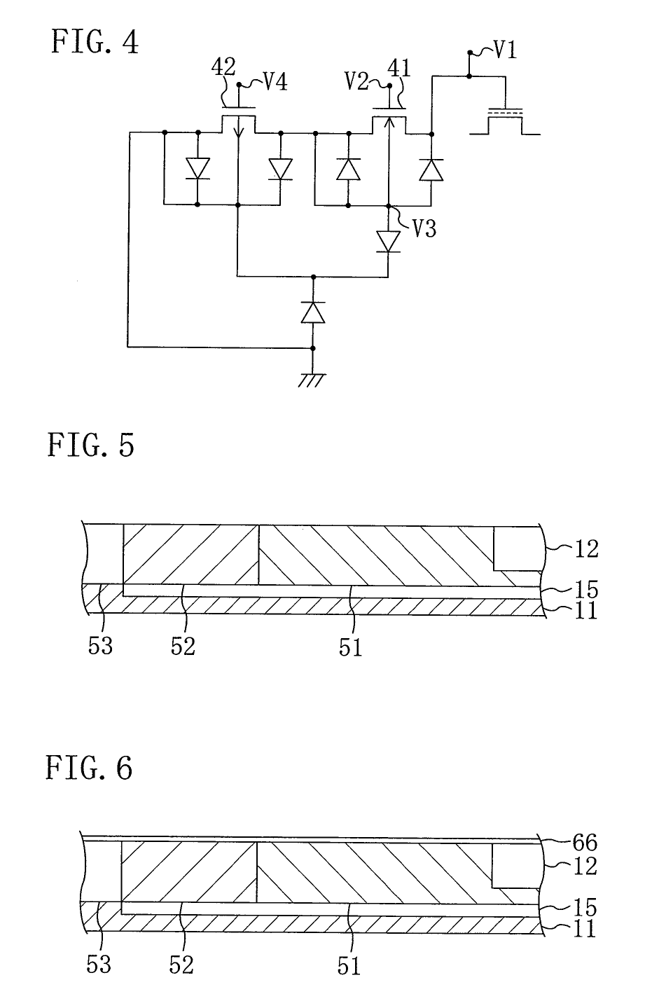

FIG. 4 shows an equivalent circuit of the illustrative semiconductor device. The equivalent circuit of FIG. 4 is depicted assuming that the first conductivity type is the p type, the second conductivity type is the n type, the first protection transistor 41 is an n-channel metal oxide semiconductor (NMOS), and the second protection transistor 42 is a p-channel metal oxide semiconductor (PMOS). Alternatively, all of the above polarities may be reversed. As shown in FIG. 4, the first protection transistor 41 and the second protection transistor 42 are connected in series with the gate electrode of the memory element as the element to be protected. The first protection transistor 41 is constructed of the first gate electrode 18A, the first source/drain diffusion layer 21A, and the second source/drain diffusion layer 21B shown in FIGS. 1A and 1B. The second protection transistor 42 is constructed of the second gate electrode 18B, the third source/drain diffusion layer 22A, and the fourth source/drain diffusion layer 22B. A plurality of diodes are connected in the circuit, which are PN junction diodes respectively formed between the diffusion layers and the wells and between the wells and the semiconductor substrate. Terminals V1, V2, V3, and V4 in FIG. 4 respectively correspond to the protected element electrode 32, the first gate electrode 18A, the first well 51, and the second gate electrode 18B.

Next, a drive method for the illustrative semiconductor device will be described. When positive charge-up has occurred during the fabrication process including steps before the wiring process, a positive voltage is applied to the terminals V1, V2, and V4 as shown in Table 1 below, turning ON the first protection transistor 41. At this time, the positive charge passes through the protected element electrode 32, the first diffusion layer 26, the first source/drain diffusion layer 21A, the channel formed under the first gate electrode 18A, the second source/drain diffusion layer 21B, the third source/drain diffusion layer 22A, the second well 52, the third diffusion layer 28, the second diffusion layer 27, and the third well 53 to escape to the semiconductor substrate 11. Hence, positive charge-up to the memory element can be suppressed.

TABLE 1

| | V1 | V2 | V3 | V4 |
|---|---|---|---|---|
| In-process positive | Positive | Positive | Ground | Positive |
| charge | | | | |
| In-process negative | Negative | Negative | Negative | Negative |
| charge | | | | |
| Write | 9 V | 0 V | 0 V | *** |
| Erase | −6 V | −6 V | −6 V | *** |
| Read | 5 V | 0 V | 0 V | *** |

As is found from the above, the positive charge is restricted by the ON current amount of the first protection transistor 41. Therefore, the first protection transistor 41 should desirably be an NMOS that has a current drive capability per gate width about twice as large as that of a PMOS, for enhancing the protection capability. Moreover, the first protection transistor 41 must be provided individually for each protected element electrode 32, and the NMOS is more suited to microfabrication than the PMOS. The reason is that arsenic contained in the source/drain diffusion layers of the NMOS is smaller in thermal diffusion coefficient than boron contained in the source/drain diffusion layers of the PMOS. Incidentally, the first well 51 and the semiconductor substrate 11 must be electrically isolated from each other. Since the semiconductor substrate 11 is generally of the p type, the n-type deep well 15, in this case, must be interposed between the p-type semiconductor substrate 11 and the p-type first well 51.

The escape of positive charge-up will be described in more detail. The protected element electrode 32 and the first diffusion layer 26 roughly form a metal junction therebetween, and hence the potential difference therebetween is roughly 0 V. The first diffusion layer 26 and the first source/drain diffusion layer 21A are of the same conductivity type, and hence the potential difference therebetween is roughly 0 V. Since positive charge is applied to the first gate electrode 18A, thereby turning ON the first protection transistor 41 at a potential of about +1 V or more, the potential difference between the first source/drain diffusion layer 21A and the second source/drain diffusion layer 21B is roughly 0 V. The second source/drain diffusion layer 21B and the third source/drain diffusion layer 22A are different in conductivity type, but both are high-density diffusion layers, and besides a salicide layer is generally formed on these diffusion layers. Hence, the potential difference therebetween is roughly 0 V. The third source/drain diffusion layer 22A and the second well 52 are forward-biased, and hence the potential difference therebetween is roughly 0 V. The second well 52 and the third diffusion layer 28 are of the same conductivity type, and hence the potential difference therebetween is roughly 0 V. The third diffusion layer 28 and the second diffusion layer 27 are different in conductivity type, but both are high-density diffusion layers, and besides a salicide layer is generally formed on these diffusion layers. Hence, the potential difference therebetween is roughly 0 V. The second diffusion layer 27, the third well 53, and the semiconductor substrate 11 are of the same conductivity type. The potential difference therebetween is therefore roughly 0 V. Thus, the positive charge applied to the protected element electrode 32 escapes to the semiconductor substrate 11, that is, to the ground potential.

When negative charge-up occurs during the fabrication process including steps before the wiring process, a negative voltage is applied to the terminals V1, V2, and V4, turning ON the second protection transistor 42 at a potential of about −1 V or less, as shown in Table 1. At this time, the negative charge passes through the protected element electrode 32, the first diffusion layer 26, the first well 51, the third source/drain diffusion layer 22A, the channel formed under the second gate electrode 18B, the fourth source/drain diffusion layer 22B, the third diffusion layer 28, the second diffusion layer 27, and the third well 53 to escape to the semiconductor substrate 11. Hence, negative charge-up to the memory element can be suppressed.

As is found from the above, the negative charge is restricted by the ON current amount of the second protection transistor 42. As already discussed with reference to the positive charge, the current drive capability per gate width of the PMOS is about a half of that of the PMOS. However, since a plurality of protected element electrodes 32 can share the second protection transistor 42 as shown in FIG. 3, the gate width of the second protection transistor 42 can be increased, permitting sufficient charge escape.

The escape of negative charge-up will be described in more detail. The protected element electrode 32 and the first diffusion layer 26 roughly form a metal junction therebetween, and hence the potential difference therebetween is roughly 0 V. The first diffusion layer 26 and the first well 51 are forward-biased, and hence the potential difference therebetween is roughly 0 V. The first well 51 and the third source/drain diffusion layer 22A are of the same conductivity type, and hence the potential difference therebetween is roughly 0 V. Since negative charge is applied to the second gate electrode 18B turning ON the second protection transistor 42, the potential difference between the third source/drain diffusion layer 22A and the fourth source/drain diffusion layer 22B is roughly 0 V. The fourth source/drain diffusion layer 22B and the third diffusion layer 28 are different in conductivity type, but both are high-density diffusion layers, and besides a salicide layer is generally formed on these diffusion layers. Hence, the potential difference therebetween is roughly 0 V. The third diffusion layer 28 and the second diffusion layer 27 are different in conductivity type, but both are high-density diffusion layers, and besides a salicide layer is generally formed on these diffusion layers. Hence, the potential difference therebetween is roughly 0 V. The second diffusion layer 27, the third well 53, and the semiconductor substrate 11 are of the same conductivity type. The potential difference therebetween is therefore roughly 0 V. Thus, the negative charge applied to the protected element electrode 32 escapes to the semiconductor substrate 11, that is, to the ground potential.

The antenna ratio of the terminal V2 is desirably set to be roughly the same or larger than that of the terminal V1. This is made to ensure that a voltage higher than the respective threshold voltages is applied to the first and second protection transistors 41 and 42, turning ON the first and second protection transistors 41 and 42, with a smaller amount of charge.

At the time of electron injection into the memory element (write operation) after completion of the fabrication process, 9 V, 0 V, and 0 V, for example, are respectively applied to the terminals V1, V2, and V3 as shown in Table 1, to turn OFF the first protection transistor 41. This makes it possible to apply a desired voltage to the memory element, to achieve electron injection into the memory element.

At the time of current readout from the memory element after completion of the fabrication process, 5 V, 0 V, and 0 V, for example, are respectively applied to the terminals V1, V2, and V3 as shown in Table 1, to turn OFF the first protection transistor 41. This makes it possible to apply a desired voltage to the memory element, to achieve current readout from the memory element.

At the time of withdrawal of electrons from the memory element or injection of holes into the memory element (erase operation) after completion of the fabrication process, −6 V, for example, is applied to the terminal V1, and −6 V, for example, is applied to the terminals V2 and V3, as shown in Table 1, to turn OFF the first protection transistor 41. This makes it possible to apply a desired voltage to the memory element, to achieve electron withdrawal from or hole injection into the memory element. Note that −7 V, for example, may be applied to the terminals V2 and V3 to put the terminals V2 and V3 at a negative potential lower (deeper) than the terminal V1. Note that the terminal V4 operates with any potential applied thereto, which is indicated by “***” in Table 1.

Table 2 below shows another drive method, in which the voltages at the time of electron injection into the memory element and at the time of current readout are the same as in Table 1. At the time of electron withdrawal or hole injection, −6 V, for example, is applied to the terminal V1, the terminal V3 is left open, and 0 V or a positive voltage is applied to the terminal V4. Since the second well 52 is at the ground potential, the second protection transistor 42 is turned OFF with this potential application, and hence a desired voltage can be applied to the memory element.

TABLE 2

| | V1 | V2 | V3 | V4 |
|---|---|---|---|---|
| In-process positive | Positive | Positive | Ground | Positive |
| charge | | | | |
| In-process negative | Negative | Negative | Negative | Negative |
| charge | | | | |
| Write | 9 V | 0 V | 0 V | *** |
| Erase | −6 V | *** | Open | 0 V |
| Read | 5 V | 0 V | 0 V | *** |

Next, an example of the method for fabricating the illustrative semiconductor device will be described with reference to the relevant drawings. First, as shown in FIG. 5, the isolation insulating film 12, the deep well 15 of the second conductivity type, the second well 52, the first well 51, and the third well 53 are respectively formed in their predetermined regions of the semiconductor substrate 11 of the first conductivity type. With this formation, a memory element region for forming the memory element as the element to be protected, a first protection transistor region for forming the first protection transistor, and a second protection transistor region for forming the second protection transistor are defined.

As shown in FIG. 6, an insulating film 66 having a thickness of 2 nm to 30 nm is formed in the memory element region, the first protection transistor region, and the second protection transistor region. Although the insulating film 66 is formed integrally in the illustrated example, independent films may be formed in the memory element region, the first protection transistor region, and the second protection transistor region. The insulating film 66 is to be the gate insulating films.

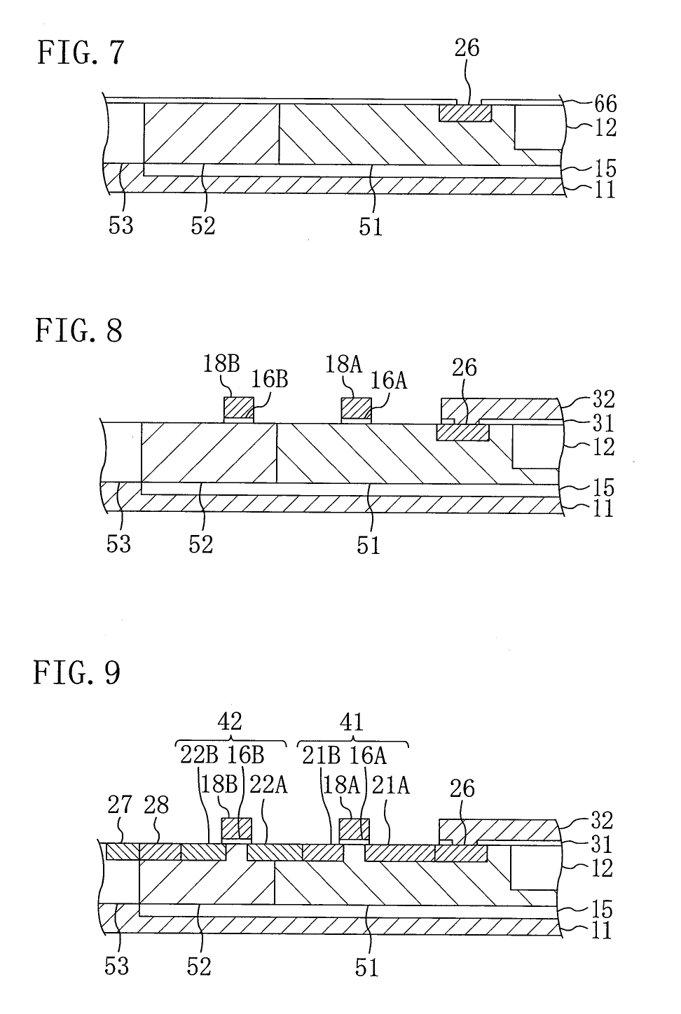

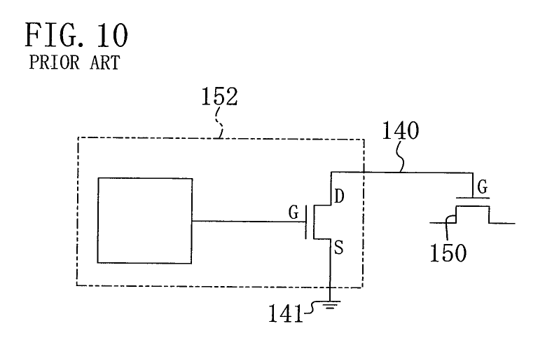

As shown in FIG. 7, an opening is formed through a portion of the insulating film 66 formed in the memory element region. Thereafter, an impurity of the second conductivity type is implanted inside the first well 51 via the opening at a dose of 1×10¹⁵/cm², for example, to form the first diffusion layer 26 of the second conductivity type.

As shown in FIG. 8, the protected element electrode 32 as the gate electrode of the memory element is formed in the memory element region, the first gate electrode 18A is formed in the first protection transistor region, and the second gate electrode 18B is formed in the second protection transistor region. The protected element electrode 32 may be formed to be in direct contact with the first diffusion layer 26 at the opening.

An insulating film having a thickness of 4 nm or less may be formed at the interface of the protected element electrode 32 and the first diffusion layer 26. As long as the thickness of the insulating film is 4 nm or less, if a voltage of about 10 V (in general, the device characteristics of a nonvolatile memory varies with a gate voltage of about 10 V) is applied to the protected element electrode 32 as in-process charge-up, a tunnel voltage will directly flow between the protected element electrode 32 and the first diffusion layer 26. Therefore, electrical connection can be sufficiently secured between the protected element electrode 32 and the first diffusion layer 26, and this will be virtually equivalent to the configuration without the insulating film. With the existence of the 4 nm or less-thick insulating film, also, abnormal growth of Si from the substrate can be suppressed, exhibiting the effect of increasing process stability.

As shown in FIG. 9, an impurity of the second conductivity type is then implanted in portions of the first well 51 on both sides of the first gate electrode 18A at a dose of 1×10¹⁵/cm², for example. With this implantation, the first source/drain diffusion layer 21A and the second source/drain diffusion layer 21B are formed on both sides of the first gate electrode 18A. This ion implantation is made so that the first source/drain diffusion layer 21A is in contact with the first diffusion layer 26. Likewise, an impurity of the first conductivity type is implanted in portions of the second well 52 on both sides of the second gate electrode 18B at a dose of 1×10¹⁵/cm², for example. With this implantation, the third source/drain diffusion layer 22A and the fourth source/drain diffusion layer 22B are formed on both sides of the second gate electrode 18B. This ion implantation is made so that the third source/drain diffusion layer 22A extends into the first well 51 to be in contact with the second source/drain diffusion layer 21B. In the second well 52, also, an impurity of the second conductivity type is implanted to form the third diffusion layer 28 to be in contact with the fourth source/drain diffusion layer 22B. Moreover, an impurity of the first conductivity type is implanted to form the second diffusion layer 27 to be in contact with the third diffusion layer 28. The order of the impurity implantation steps is not specifically limited. Also, the impurity implantation steps of the same conductivity type may be combined.

A metal silicide layer is preferably formed on the first source/drain diffusion layer 21A, the second source/drain diffusion layer 21B, the third source/drain diffusion layer 22A, the fourth source/drain diffusion layer 22B, and the third diffusion layer 28. When no metal silicide layer is formed, the connection between the second source/drain diffusion layer 21B of the second conductivity type and the third source/drain diffusion layer 22A of the first conductivity type and the connection between the fourth source/drain diffusion layer 22B of the first conductivity type and the third diffusion layer 28 of the second conductivity type are made using a low breakdown voltage at the PN junction between the high-density impurity-diffused layers at the time of reverse biasing. However, with the formation of the metal silicide layer, which permits direct metal junction, the connectivity improves, and hence the charge-up protection voltage range during the fabrication process can be made lower.

As described above, while the effect of protecting the element to be protected is exhibited only in and after the wiring process in the conventional technique, it can be exhibited in and after the FEOL process in the semiconductor device of the present disclosure.

While a negative voltage cannot be applied to the element to be protected after completion of the fabrication process in the conventional semiconductor device from the standpoint of its structure, high voltages of both positive and negative polarities can be applied to the element to be protected after completion of the fabrication process in the semiconductor device of the present disclosure.

In the illustrative semiconductor device, the gate electrode of the memory element as the element to be protected and the source/drain diffusion layer of the first protection transistor are connected to each other via the first diffusion layer, to exhibit the protection effect in and after the FEOL process. It is also useful to adopt the structure of connecting the gate electrode of the memory element with the source/drain diffusion layer of the first protection transistor via an interconnect as in the conventional technique. In this case, although the element to be protected will be protected only in and after the wiring process, a negative high voltage can be applied to the memory element for driving the memory element after completion of the fabrication process. In this case, also, since the diffusion layers in the substrate are not directly connected, the number of fabrication steps and the degree of fabrication difficulty can be reduced.

As described above, in the semiconductor device and the drive method for the same of the present disclosure, high voltages of both positive and negative polarities required for driving a memory element can be applied to the memory element after completion of the fabrication process. Also, the memory element can be protected from charge-up during diffusion process in the FEOL process within a voltage range including a low voltage, positive or negative, as required. Hence, the present disclosure is especially useful for a semiconductor device such as a local charge storage nonvolatile memory and a drive method for the same.

The description of the embodiments of the present invention is given above for the understanding of the present invention. It will be understood that the invention is not limited to the particular embodiments described herein, but is capable of various modification, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A semiconductor device, comprising:
a deep well of a second conductivity type formed in a semiconductor substrate of a first conductivity type;
a first well of the first conductivity type formed in an upper portion of the deep well;
a second well of the second conductivity type formed in the semiconductor substrate;
an element to be protected formed on the semiconductor substrate, the element having a protected element electrode;
a first protection transistor formed on the first well;
a second protection transistor formed on the second well;
a first diffusion layer of the second conductivity type formed in the first well to be electrically connected with the protected element electrode; and
a second diffusion layer of the first conductivity type formed in an upper portion of the semiconductor substrate,
wherein
the first protection transistor includes a first gate electrode formed on the first well and first and second source/drain diffusion layers of the second conductivity type formed in the semiconductor substrate adjacent to the gate electrode,
the second protection transistor includes a second gate electrode formed on the second well and third and fourth source/drain diffusion layers of the first conductivity type formed in the semiconductor substrate adjacent to the gate electrode,
the first source/drain diffusion layer is in contact with the first diffusion layer,
the second source/drain diffusion layer is electrically connected with the third source/drain diffusion layer and at the same potential as the first well, and
the fourth source/drain diffusion layer is electrically connected with the second diffusion layer and at the same potential as the second well and the second diffusion layer.

2. The semiconductor device of claim 1, further comprising:
a third well of the first conductivity type formed in the semiconductor substrate, wherein
the second diffusion layer of the first conductivity type is formed in the third well.

3. The semiconductor device of claim 1, further comprising:
a third diffusion layer of the second conductivity type formed in the second well, wherein
the third diffusion layer is in contact with the fourth source/drain diffusion layer and the second diffusion layer.

4. The semiconductor device of claim 1, further comprising:
a fourth diffusion layer of the first conductivity type formed in the first well, wherein
the fourth diffusion layer is in contact with the third source/drain diffusion layer.

5. The semiconductor device of claim 4, wherein the fourth diffusion layer is formed integrally with the third source/drain diffusion layer.

6. The semiconductor device of claim 1, further comprising:
an insulating film having a thickness of 4 nm or less formed between the protected element electrode and the first diffusion layer,
wherein
the protected element electrode and the first diffusion layer are electrically connected with each other by a tunnel current passing through the insulating film.

7. The semiconductor device of claim 1, wherein the first diffusion layer is formed integrally with the first source/drain diffusion layer.

8. The semiconductor device of claim 1, wherein at least part of the second well is formed in an upper portion of the deep well.

9. The semiconductor device of claim 1, wherein the element to be protected is a nonvolatile memory whose memory state varies with storage or removal of an electron or a hole in or from a charge storage layer.

10. A drive method for the semiconductor device of claim 1, comprising the steps of:
during first operation in which a positive voltage is applied to the protected element electrode, applying a ground voltage to the first gate electrode and the first well; and
during second operation in which a negative voltage is applied to the protected element electrode, applying a negative voltage equal to or lower than the above negative voltage to the first gate electrode and the first well.

11. A drive method for the semiconductor device of claim 1, comprising the steps of:
during first operation in which a positive voltage is applied to the protected element electrode, applying a ground voltage to the first gate electrode and the first well; and
during second operation in which a negative voltage is applied to the protected element electrode, applying a ground voltage or a positive voltage to the second gate electrode.
